(19) United States
(12) Patent Application Publication
(10) Pub. No.: US 2012/0039485 A1
(43) Pub. Date: Feb. 16, 2012

(54) HIGH FIDELITY PHONOGRAPHIC PREAMPLIFIER FEATURING SIMULTANEOUS FLAT AND PLAYBACK COMPENSATION CURVE CORRECTION OUTPUTS

(76) Inventor: Robert S. Robinson, Trenton, NJ (US)

(21) Appl. No.: 13/208,685

(22) Filed: Aug. 12, 2011

Related U.S. Application Data
(60) Provisional application No. 61/373,521, filed on Aug. 13, 2010.

(51) Int. Cl. H03G 5/16; H03G 3/00

(52) U.S. Cl. 381/103; 381/107

(57) ABSTRACT

An audio playback system and method including an analog preamplifier configured to produce simultaneous “flat” and response-compensated outputs, to enable playback of a phonograph recording via an all-analog signal pathway, while optionally providing for the simultaneous digital recording and/or monitoring of the “flat,” uncompensated signal.

### CROSS REFERENCE TO RELATED APPLICATION

This application claims to the benefit of U.S. Provisional Application 61/373,521 filed Aug. 13, 2010, which is hereby incorporated by reference in its entirety.

### TECHNICAL FIELD

Embodiments of the present invention relate to an audio playback system and method.

### BACKGROUND

The resurgence in consumer interest in pre-digital audio music recordings, such as “vinyl” LP records, along with the associated playback hardware, has spurred efforts to implement playback frequency response compensation curves in the digital domain.

Conventional analog phonograph preamplifiers provide playback frequency response compensation as part of their design. Vinyl records produced within about the last 50 years employ the standardized Recording Industry Association of America (RIAA) emphasis or frequency response compensation curve. This curve dictates a rising high frequency emphasis of approximately 20 dB at 20 kHz and a similar low frequency attenuation at 20 Hz, applied before manufacturing the vinyl disc (i.e., an original pre-manufacturing analog signal). The playback of such material requires the application of a complementary compensation curve to restore proper frequency balance. This is typically done with circuitry that is integrated into a preamplifier configured to properly amplify and condition the phonograph signal.

Prior to the introduction of the standard RIAA compensation curve, frequency response compensation was still required, but could be performed using any known proprietary compensation curves specified by the various manufacturers of phonograph recordings, even in the era before the “long playing” vinyl record was introduced (i.e., when “shellac” was used as the substrate for the manufactured product).

Eschewing compensation in the analog domain for its digital counterpart permits the realization of a closer agreement with the specified compensation curve, with less cost and effort compared to practically attainable analog circuitry. The accuracy of digital compensation can be engineered to achieve nearly any arbitrary specification limit. Applying compensation in the digital domain also confers immunity to analog filter component tolerances and their variation due to temperature and aging. For a multichannel signal, all channels will have identical compensation (amplitude and phase response). Further, implementing compensation curves utilizing software makes it easier to accommodate the plethora of antique recordings and their arcane compensation curves, which predate the RIAA standard.

Finally, digital compensation allows for the restoration (such as the removal of transient clicks or pops) of damaged recordings for archival or other purposes. While the music signal has been subjected to a pre-emphasis curve, subsequent physical defects in the recording medium have not. Therefore, the compensation curve distorts and stretches a defect's transient signal. If defects are excised prior to application of the compensation curve, artifacts resulting from their removal are minimized. Digital compensation could also be implemented for use with digital playback compensation of magnetic tape recordings. These benefits are realized when access to the “flat” or uncompensated signal is available.

Prior to the advent of digital frequency response compensation, a “flat” output phonograph preamplifier was of little utility. With digital frequency response compensation, such preamplifiers have become a necessity. However, this also requires digital signal processing capability being available and connected to the “flat” output for signal processing, such as a computer and analog to digital conversion hardware. Without response compensation required for playing back all phonograph recordings, listening to the phonograph playback directly from a “flat” preamplifier is undesirable.

However, conventional preamplifier products do not simultaneously produce “flat” and compensated outputs, which may be valued by audiophiles desiring to listen via an all-analog signal path while simultaneously capturing the signal digitally.

Furthermore, conventional preamplifiers that are provided with a selector switch to toggle between “flat” and compensated outputs require the user to physically change the connection from the computer ADC input used for “flat” playback to the audio playback system used for only analog playback, which can be an inconvenient operation.

### BRIEF DESCRIPTION OF THE DRAWINGS

FIG. 1 illustrates an exemplary embodiment of an analog phonograph playback system.

FIG. 2 illustrates an exemplary embodiment of an analog phonograph playback system.

### DETAILED DESCRIPTION

Embodiments of the present invention provide an audio playback system and method configured to simultaneously produce “flat” and compensated outputs while simultaneously capturing the signal digitally. Advantageously, embodiments of the system and method may also be used without associated computer or DSP hardware without having to reconfigure the preamplifier outputs, because of the simultaneous availability of the compensated signal.

Embodiments of the present invention represent an enhancement to phonograph playback preamplifiers, in light of relatively recent developments in the field of digital audio signal processing.

In an embodiment, the audio playback system comprises a preamplifier explicitly designed to produce simultaneous “flat” and response-compensated (“RIAA Corrected”) outputs. The audio playback system enables playback of the phonograph recording via an all-analog signal pathway, while also providing for the simultaneous digital recording or monitoring of the “flat,” uncompensated signal. Alternatively, the audio playback system may be configured to allow a user to choose between these two signals without having to reconfigure external signal connections or activate a selector mechanism, because both signals are produced concurrently by the system.

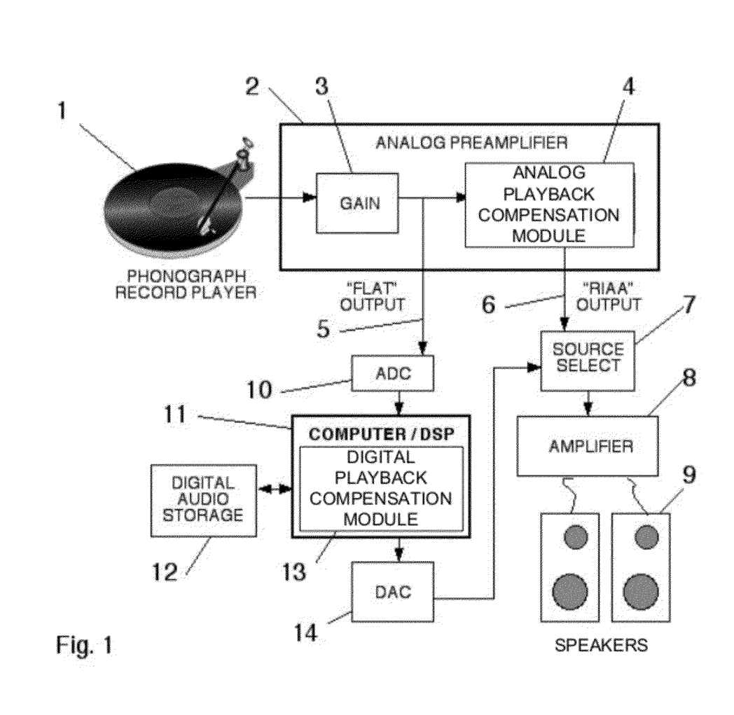

FIG. 1 illustrates an analog phonograph playback system in an exemplary audio playback environment, according to embodiments of the present invention. The audio playback environment shown in FIG. 1 comprises an audio source (i.e., Phonograph Record Player 1) communicatively connected to an Analog Preamplifier 2. The Phonograph Record Player 1 is a commonly available commercially manufactured type of device consisting of turntable, tone arm and phonograph cartridge, which supplies the audio signal to the preamplifier. “Vinyl” LP or older shellac substrate discs are the physical medium used for delivering audio recordings.

In an embodiment, the Analog Preamplifier 2 comprises a linear Gain Module 3 (configured to provide a suitable level of gain, such as, for example, approximately 20 to 70 dB of gain) coupled to a Analog Playback Compensation Module 4. The Gain Module 3 is configured to provide signal gain and may be implemented with commonly available electronic components. The Analog Playback Compensation Module 4 is configured to restore a proper frequency balance of all phonograph recordings. In an embodiment, the Analog Preamplifier 2 is configured to simultaneous produce a “flat” analog signal output (“Flat Output 5”) and a compensated or “RIAA” output 6 (also referred to as a “first compensated analog signal”).

The Analog Preamplifier 2 provides gain and signal conditioning to the analog audio signal received from the Phonograph Record Player 1. In an embodiment, the Gain Module 3 may be tightly integrated with the Analog Playback Compensation Module 4, placing both functions into the same functional (physical) module. The Analog Playback Compensation Module 4 is configured to supply an inverse of the necessary signal conditioning and equalization applied to the original pre-manufacturing analog signal during the LP manufacturing process. The compensation alters the frequency balance of the audio that is complementary to that applied during manufacturing, the desired result being retrieval of the original signal with its original frequency balance. In an embodiment, the Compensated Output 6 is directed to an optional Selector Switch 7 that permits selecting various audio signal sources directed to the Amplifier 8, wherein the output of the Amplifier 8 drives Speakers 9.

The Selector Switch 7 may be any suitable user-operated electromechanical switch that allows the user to select various signal sources. Optionally, the audio playback environment may include an amplifier (“Amplifier 8”) and a sound producing component (“Speakers 9”), which may be any suitable components that are commercially available and used in conventional audio playback environments.

According to embodiments of the present invention, the analog playback may be used simultaneously with the digital recording or signal processing performed by digital audio hardware components of the audio playback system on the Flat Output 5. In an embodiment, the digital audio hardware comprises an analog to digital converter (“Analog to Digital Converter (ADC) 10”) coupled to a host computer or “Digital Signal Processing (DSP) System 11.”

The digital signal processed by the DSP System 11 may optionally be stored in a suitable computer memory (“Digital Audio Storage 12”), such as a computer hard disk drive, either in unaltered, “flat” form or after further signal processing. In an embodiment, the audio playback system comprises a digital signal processing software module (“Digital Playback Compensation Module 13”) executed on the host computer or embedded in the DSP hardware as loadable software or firmware which performs the necessary playback signal compensation, the same as the Analog Playback Compensation Module 4 employed in the analog preamplifier required to restore the proper frequency balance of all phonograph recordings. In an embodiment, the digital signal may then be converted back to an analog signal by a digital to analog converter (“Digital to Analog Converter (DAC) 14”) to produce a compensated analog signal (also referred to as a “second compensated analog signal”). The Selector Switch 7 may be used to select either the Analog Compensated Signal 6 (i.e., the first compensated analog signal) or the response compensated signal output by the Digital to Analog Converter 14 (the second compensated analog signal). Alternatively, the signal output by Digital to Analog Converter 14 could be connected directly to Amplifier 8.

One having ordinary skill in the art will appreciate that the Analog to Digital Converter 10 and the Digital to Analog Converter 14 may be any suitable commercially available converters, including those that are a part of various commercially manufactured “computer audio interfaces” meant for digital audio recording and playback. The host computer may be any commercially available computing device capable of connecting to a computer audio interface. The signal processing software that implements the Digital Playback Compensation Module 13 in the digital domain is part of a compiled application running on the host computer. Digital Audio Storage 12, again, can be any of a number of commercially available, off-the-shelf data storage products (hard disks or solid state drives, digital tape, optical discs). Another implementation of the digital hardware may be a specially designed digital signal processor with embedded signal processing software.

In an embodiment, the first compensated analog signal produced by the audio playback system includes an amplitude versus frequency balance that matches an amplitude versus frequency balance of an original pre-manufacturing analog signal (i.e., the analog signal of the audio prior to applying the RIAA emphasis). In addition, according to an embodiment of the present invention, the audio playback system produces a first compensated analog signal and a second compensated analog signal that match an original pre-manufacturing analog signal.

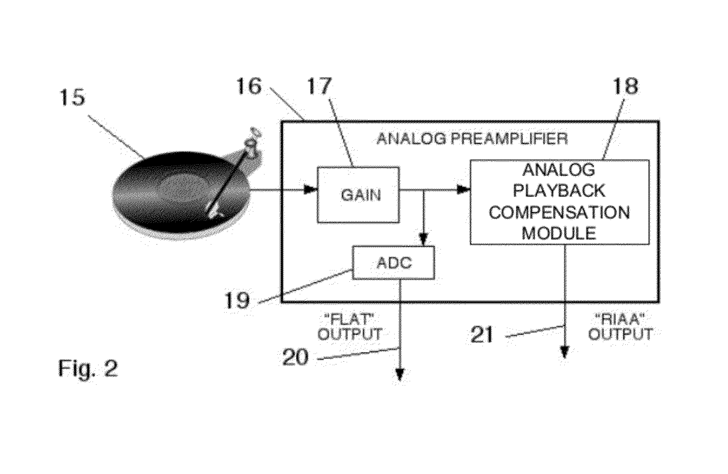

FIG. 2 illustrates an alternative embodiment of the present invention in which an Analog to Digital Converter (ADC) 19 is incorporated into the same physical unit (e.g., having the same chassis) as an Analog Preamplifier 16. The exemplary Analog Preamplifier 16 shown in FIG. 2 is configured to include the features and functionality of the Analog Preamplifier 2 shown in FIG. 1. The Analog Preamplifier 16 is configured to receive an analog audio signal from a Phonograph Record Player 15 and includes a Gain Module 17 which drives an Analog Playback Compensation Module 18 and ADC 19. The Analog Preamplifier 16 is configured to simultaneously produce a “flat” signal (“Flat Output 20”) at the digital output of the ADC 20 and a compensated output (“RIAA Output 21”) of the Analog Playback Compensation Module 18.

Certain portions of the embodiments may be implemented as a computer program product that may include instructions stored on a computer-readable medium. These instructions may be used to program a general-purpose or special-purpose processor to perform the described operations. A computer-readable medium includes any mechanism for storing or transmitting information in a form (e.g., software, processing application) readable by a machine (e.g., a computer). The computer-readable storage medium may include, but is not limited to, magnetic storage medium (e.g., floppy diskette); optical storage medium (e.g., CD-ROM); magneto-optical storage medium; read-only memory (ROM); random-access memory (RAM); erasable programmable memory (e.g., EPROM and EEPROM); flash memory, or another type of medium suitable for storing electronic instructions. The computer-readable transmission medium includes, but is not limited to, electrical, optical, acoustical, or other form of propagated signal (e.g., carrier waves, infrared signals, digital signals, or the like), or another type of medium suitable for transmitting electronic instructions.

Additionally, some embodiments may be practiced in distributed computing environments where the computer-readable medium is stored on and/or executed by more than one computer system. In addition, the information transferred between computer systems may either be pulled or pushed across the transmission medium connecting the computer systems.

Although the operations of the method(s) herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

The particular features, structures or characteristics described herein may be combined as suitable in one or more embodiments of the invention. In addition, while the present invention has been described in terms of several embodiments, those skilled in the art will recognize that the invention is not limited to the embodiments described. The embodiments of the invention can be practiced with modification and alteration within the scope of the appended claims. The specification and the drawings are thus to be regarded as illustrative instead of limiting on the invention.

What is claimed is:

1. An analog preamplifier comprising:
a gain module configured to:
receive an analog audio signal from an audio source,
supply gain to the analog audio signal, and
produce a flat analog signal for output to a user; and
an analog playback compensation module configured to produce a first compensated analog signal based on the flat analog signal for output to the user.

2. The analog preamplifier of claim 1, wherein the analog playback compensation module is configured to alter a frequency balance level of the analog audio signal to complement a frequency balance level applied during manufacturing of the audio source.

3. The analog preamplifier of claim 1, wherein the first compensated analog signal matches an original pre-manufacturing analog signal.

4. The analog preamplifier of claim 3, wherein an amplitude versus frequency balance of the first compensated analog signal matches an amplitude versus frequency balance of the original pre-manufacturing analog signal.

5. The analog preamplifier of claim 1 further comprising an analog to digital converter configured to convert the flat analog signal to a digital signal.

6. An audio playback system comprising:
an analog preamplifier comprising:
a gain module configured to:
receive an analog audio signal from an audio source,
supply gain to the analog audio signal, and
produce a flat analog signal, and
an analog playback compensation module configured to produce a first compensated analog signal based on the flat analog;
an analog to digital converter configured to convert the flat analog signal to a digital signal; and
a digital signal processor configured to compensate the digital signal received from the analog to digital converter to produce a compensated digital signal.

7. The audio playback system of claim 6 further comprising a digital to analog converter configured to convert the compensated digital signal to a second compensated analog signal.

8. The audio playback system of claim 7 further comprising a selector switch configured to receive a selection for playback of one of the first compensated analog signal and the second compensated analog signal.

9. The audio playback system of claim 7, wherein the second compensated analog signal matches an original pre-manufacturing analog signal.

10. The audio playback system of claim 6, wherein the analog playback compensation module is configured to supply an inverse of signal conditioning and equalization applied during manufacturing of the audio source.

11. The audio playback system of claim 6, wherein the digital signal processor is configured to produce the compensated digital signal by altering a frequency balance level of the digital audio signal to complement a frequency balance level applied during manufacturing of the audio source.

12. The audio playback system of claim 6, wherein the digital signal processor is configured to produce the compensated digital signal by supplying an inverse of signal conditioning and equalization applied during manufacturing of the audio source.

13. The audio playback system of claim 6, wherein the first compensated analog signal matches an original pre-manufacturing analog signal.

14. The audio playback system of claim 13, wherein an amplitude versus frequency balance of the first compensated analog signal matches an amplitude versus frequency balance of the original pre-manufacturing analog signal.

15. A method of playback of audio, comprising:
receiving an analog audio signal from an audio source;
supplying gain to the analog audio signal to produce an amplified analog audio signal;
producing a flat analog signal based on the amplified analog audio signal; and
compensating the amplified analog audio signal in an analog domain to produce a first compensated analog signal.

16. The method of playback of audio of claim 15 further comprising converting the flat analog signal to a digital signal.

17. The method of playback of audio of claim 16 further comprising compensating the digital signal in a digital domain to produce a compensated digital signal.

18. The method of playback of audio of claim 17 further comprising converting the compensated digital signal to a second compensated analog signal.

19. The method of playback of audio of claim 18, wherein the second compensated analog signal matches an original pre-manufacturing analog signal.

20. The method of playback of audio of claim 18 further comprising receiving a selection of one of the first compensated analog signal and the second compensated analog signal for playback.

21. The method of playback of audio of claim 17, wherein compensating the digital signal in the digital domain comprises altering a frequency balance of the digital signal to a level that is complementary to a frequency balance applied during manufacturing of the audio source.

22. The method of playback of audio of claim 17, wherein compensating the digital signal in the digital domain comprises supplying an inverse of signal conditioning and equalization applied during manufacturing of the audio source.

23. The method of playback of audio of claim 15, wherein compensating the amplified analog audio signal in the analog domain comprises altering a frequency balance of the amplified analog audio signal to a level that is complementary to a frequency balance applied during manufacturing of the audio source.

24. The method of playback of audio of claim 15, wherein compensating the amplified analog audio signal in the analog domain comprises supplying an inverse of signal conditioning and equalization applied during manufacturing of the audio source.

25. The method of playback of audio of claim 15, wherein the first compensated analog signal matches an original pre-manufacturing analog signal.

26. The method of playback of audio of claim 25, wherein an amplitude versus frequency balance of the first compensated analog signal matches an amplitude versus frequency balance of the original pre-manufacturing analog signal.
